(19) United States
(12) Patent Application Publication
(10) Pub. No.: US 2025/0287761 A1
(43) Pub. Date: Sep. 11, 2025

(54) LIGHT-EMITTING DEVICE AND MANUFACUTRING METHOD OF LIGHT-EMITTING DEVICE

(71) Applicant: STANLEY ELECTRIC CO., LTD., Meguro-ku, Tokyo (JP)

(72) Inventors: Kenji TABUCHI, Tokyo (JP); Daizo KAMBARA, Tokyo (JP); Yuji SHIGEEDA, Tokyo (JP); Daisuke WATANABE, Tokyo (JP)

(73) Assignee: STANLEY ELECTRIC CO., LTD., Meguro-ku, Tokyo (JP)

(21) Appl. No.: 18/858,359

(22) PCT Filed: Apr. 10, 2023
(86) PCT No.: PCT/JP2023/014506

§ 371 Date: Oct. 21, 2024

(30) Foreign Application Priority Data
Apr. 22, 2022 (JP) 2022-070834

(51) Int. Cl. H10H 29/85; H10H 29/01

(52) U.S. Cl. CPC H10H 29/857; H10H 29/0364; H10H 29/8508

(57) ABSTRACT

A light-emitting device includes an insulating substrate having one or more first cutouts and one or more second cutouts provided on opposite side surfaces thereof. First and second wiring electrodes, which are separated from each other, correspond respectively to the first and second cutouts. The first and second wiring electrodes each cover a region that extends over an edge of the corresponding cutout on an upper surface of the substrate and a region that extends over an edge the corresponding cutout on a lower surface of the substrate from an internal surface of the cutout. First and second resin films cover surfaces the first and second wiring electrodes in regions that extend over edges along the first and second cutouts in a top view. A light-emitting element is placed on the substrate to allow power to be supplied by the first wiring electrode and the second wiring electrode.

### TECHNICAL FIELD

The present invention relates to a light-emitting device including a semiconductor light-emitting element and a manufacturing method of the same.

### BACKGROUND ART

There has been known a surface-mounted LED called a chip LED as a small-sized light-emitting device in which a light-emitting element, such as a light emitting diode (LED), is used as a light source.

For example, Patent Document 1 discloses a surface-mounted light emitting diode as a light-emitting device having a structure in which a cathode electrode and an anode electrode formed on the upper surface of a glass epoxy substrate including a light-emitting diode element are routed to a back surface electrode formed on the back surface side of the glass epoxy substrate through respective through-hole electrodes disposed at both end portions of the glass epoxy substrate.

In addition, in the surface-mounted light emitting diode disclosed in Patent Document 1, it is described that masking tape is affixed to the upper surfaces of the through-hole electrodes, and a second resin is placed on the entire upper surface of the glass epoxy substrate including the top of the masking tape.

Patent Document 1: Japanese Unexamined Patent Application Publication No. 2000-261041

### DISCLOSURE OF THE INVENTION

### Problems to be Solved by the Invention

In the surface-mounted light emitting diode disclosed in Patent Document 1, the masking tape is used to stop the second resin from flowing into the through-hole electrodes during the formation of the second resin.

Similarly to the surface-mounted light emitting diode disclosed in Patent Document 1, if a second resin, which is a sealing resin, is formed on the entire upper surface of a glass epoxy substrate that has been subjected to thermosetting treatment by impregnating glass fibers with epoxy resin, the amount of resin material used may increase, and the cost may rise.

However, in a case where the structure is configured to suppress the amount of resin material used such that the resin material does not cover the through-hole electrodes in the light-emitting device, when individualization of the light-emitting device is performed by dicing, delamination may occur on the through-hole electrodes, the cathode electrode, the anode electrode, or the back surface electrode, which are exposed to dicing surfaces as side surfaces of the light-emitting device, causing a failure.

Furthermore, in a case where a plurality of pairs of electrodes are formed on the glass epoxy substrate, when the light-emitting device is mounted on a mounting substrate, solder may excessively crawl up through the through-hole electrodes. If the solder crawls onto the glass epoxy substrate, insufficient solder on the mounting surface may cause a failure in die shear strength.

The present invention has been made in consideration of the above-described points and an object of which is to provide a light-emitting device that allows improving mountability of the light-emitting device while suppressing a failure in manufacturing and a manufacturing method of the light-emitting device.

### Solutions to the Problems

A light-emitting device according to the present invention includes an insulating substrate, a first wiring electrode, a second wiring electrode, a first resin film, a second resin film, and a light-emitting element. The insulating substrate has an approximately rectangular upper surface shape and having one or a plurality of first cutouts and one or a plurality of second cutouts. The one or the plurality of first cutouts are formed on one side surface of one set of opposed side surfaces. The one or the plurality of second cutouts are formed on another side surface of the one set of side surfaces. The first wiring electrode covers a region that extends over an edge of each of the one or the plurality of first cutouts on an upper surface of the substrate and a region that extends over an edge of each of the one or the plurality of first cutouts on a lower surface of the substrate from an internal surface of each of the one or the plurality of first cutouts. The second wiring electrode is separated from each of the first wiring electrodes. The second wiring electrode covers a region that extends over an edge of each of the one or the plurality of second cutouts on the upper surface of the substrate and a region that extends over an edge of each of the one or the plurality of second cutouts on the lower surface of the substrate from an internal surface of each of the one or the plurality of second cutouts. The first resin film covers a surface of each of the first wiring electrodes in each of regions that extend over edges along the one or the plurality of first cutouts in a top view viewed from a direction perpendicular to the upper surface of the substrate. The second resin film covers a surface of each of the second wiring electrodes in a region extending over edges along the one or the plurality of second cutouts in the top view. The light-emitting element is placed on the substrate to allow power to be supplied by the first wiring electrode and the second wiring electrode.

A manufacturing method of a light-emitting device according to the present invention includes: a step of preparing a substrate structure having an insulating substrate and copper foil layers formed on an upper surface and a lower surface of the substrate; a through hole forming step of forming a plurality of through holes arranged in a plurality of rows on the upper surface of the substrate structure, each of the plurality of through holes penetrating from the upper surface to the lower surface of the substrate structure; a first plating step of forming a copper layer on surfaces of the copper foil layers and inner surfaces of the plurality of through holes by plating; a wiring pattern forming step of forming a wiring pattern by etching each of the copper foil layers and the copper layer on the upper surface and the lower surface of the substrate; a resin film forming step of forming a resin film covering a region along an outer edge of each of the plurality of through holes on a surface of a part of the wiring pattern formed on the upper surface of the substrate structure; and an individualization step of individualizing by cutting the substrate structure so as to separate each of the plurality of through holes along dicing lines extending along the plurality of rows.

### BRIEF DESCRIPTION OF THE DRAWINGS

FIG. 1 is a top view of a light-emitting device according to an embodiment of the present invention.

FIG. 2 is a cross-sectional view of the light-emitting device according to the embodiment of the present invention.

FIG. 3 is a diagram illustrating a manufacturing process of the light-emitting device according to the embodiment of the present invention.

FIG. 4 is a diagram illustrating the manufacturing process of the light-emitting device according to the embodiment of the present invention.

FIG. 5A is a top view of the light-emitting device according to the embodiment of the present invention in manufacturing.

FIG. 5B is a cross-sectional view of the light-emitting device according to the embodiment of the present invention in manufacturing.

FIG. 6A is a top view of the light-emitting device according to the embodiment of the present invention in manufacturing.

FIG. 6B is a cross-sectional view of the light-emitting device according to the embodiment of the present invention in manufacturing.

FIG. 7 is a top view of the light-emitting device according to the embodiment of the present invention in manufacturing.

FIG. 8 is a cross-sectional view of the light-emitting device according to the embodiment of the present invention in manufacturing.

FIG. 9 is a top view of the light-emitting device according to the embodiment of the present invention in manufacturing.

FIG. 10 is a cross-sectional view illustrating an example of a mounted state of the light-emitting device according to the embodiment of the present invention.

FIG. 11A is a top view of a light-emitting device according to a modification of the present invention.

FIG. 11B is a cross-sectional view of the light-emitting device according to the modification of the present invention.

### DESCRIPTION OF PREFERRED EMBODIMENTS

The following describes an embodiment of the present invention in detail. In the following description and attached drawings, same reference numerals are given to actually same or equivalent parts.

### Embodiment

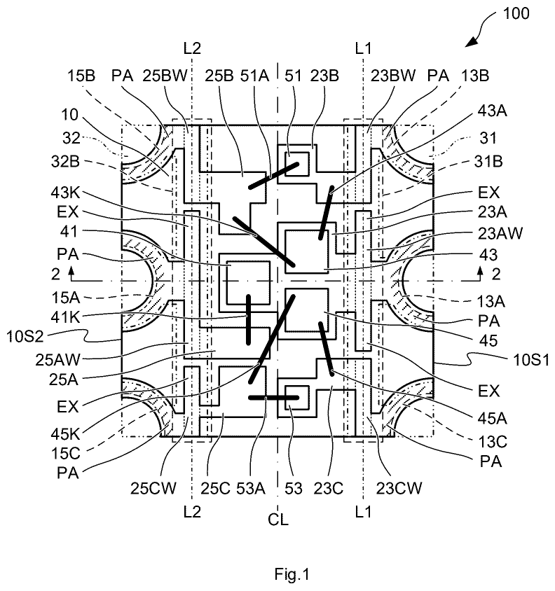

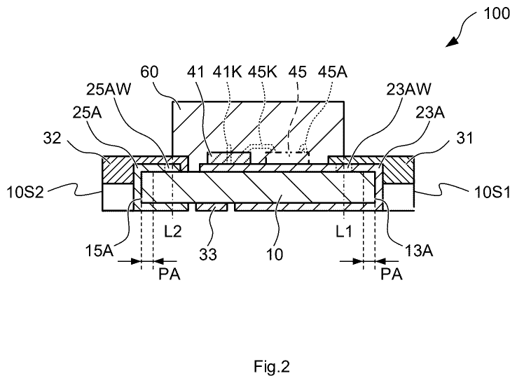

With reference to FIG. 1 and FIG. 2, a configuration of a light-emitting device 100 according to an embodiment is described. FIG. 1 is a top view of the light-emitting device 100 according to the embodiment. FIG. 2 is a cross-sectional view taken along a line 2-2 of the light-emitting device 100 illustrated in FIG. 1.

In FIG. 1, a first resin film 31 and a second resin film 32 are indicated by two-dot chain lines in order to clarify the structure and positional relationship of each element on an upper surface of a substrate 10. Additionally, in FIG. 1, a sealing member 60 (see FIG. 2) is not illustrated in order to clarify the structure and positional relationship of each element on the upper surface of the substrate 10.

### Light-Emitting Device

The light-emitting device 100 has the substrate 10 that has an approximately rectangular upper surface shape and has cutouts 13A, 13B, 13C as three first cutouts and cutouts 15A, 15B, 15C as three second cutouts formed on respective opposed sides. In the following description, the cutouts 13A, 13B, 13C are collectively referred to as cutouts 13A-C, and the cutouts 15A, 15B, 15C are collectively referred to as cutouts 15A-C in some cases.

In addition, the light-emitting device 100 has light-emitting elements 41, 43, 45 and protection elements 51, 53 on the upper surface of the substrate 10.

Moreover, the light-emitting device 100 has the sealing member 60 (see FIG. 2) that seals the light-emitting elements 41, 43, 45 and the protection elements 51, 53 on the upper surface of the substrate 10.

In the embodiment, each component is placed in each of a plurality of light-emitting device formation regions arranged in a matrix on one flat plate substrate, and individualization by dicing is performed to manufacture a plurality of light-emitting devices 100. Therefore, each side surface of the light-emitting device 100 is a dicing surface cut by dicing.

The embodiment describes a case where the respective three light-emitting elements 41, 43, 45 are connected in parallel in the light-emitting device 100. That is, the light-emitting device 100 of the embodiment is a light-emitting device that has three pairs of anode electrodes and cathode electrodes and can control the three light-emitting elements 41, 43, 45 individually.

### Substrate

The substrate 10 is an insulating substrate having an approximately rectangular upper surface shape. The substrate 10 has a planar shape in which parts of one set of sides opposed to one another are cut out of a rectangle indicated by dashed lines in a top view. In other words, in the substrate 10, cutouts are formed on parts of opposed side surfaces 10S1 and 10S2. Hereinafter, the center line parallel to the above-described one set of sides of the substrate 10 is described as a center line CL.

The respective cutouts 13A, 13B, 13C as the first cutouts and the respective cutouts 15A, 15B, 15C as the second cutouts are formed at the center and both ends of each of the side surface 10S1 and the side surface 10S2 of the substrate 10 by penetrating from the upper surface to a lower surface of the substrate 10.

The cutout 13A, the cutout 13B, and the cutout 13C and the cutout 15A, the cutout 15B, and the cutout 15C are formed at positions to be opposed across the center line CL.

The cutout 13A and the cutout 15A are formed at the respective centers of the side surfaces 10S1 and 10S2 in the top view in a shape obtained by cutting an approximately semicircular shape from the rectangular substrate 10. In addition, the cutouts 13B, 13C and the cutouts 15B, 15C are formed at respective both ends of the side surfaces 10S1 and 10S2 in the top view in a shape obtained by cutting a fan shape from the rectangular substrate 10.

In the embodiment, a flat plate made of glass epoxy was used as the substrate 10. In addition, in the embodiment, a glass epoxy flat plate having a thickness of about 100 μm was used.

### Wiring Electrode

Each of wiring electrodes 23A, 23B, 23C as first wiring electrodes and wiring electrodes 25A, 25B, 25C as second wiring electrodes is a conductive wiring electrode formed on a surface of the substrate 10.

The respective wiring electrodes 23A, 23B, 23C and the respective wiring electrodes 25A, 25B, 25C are formed over respective edges of the corresponding cutouts 13A-C and respective edges of the corresponding cutouts 15A-C on the upper surface of the substrate 10.

The wiring electrodes 23A, 23B, 23C continuously extend from parts formed at the respective edges of the cutouts 13A-C to bonding pad portions and element placing portions disposed in a central region along the center line CL of the substrate 10 via routing portions 23AW, 23BW, 23CW, respectively. The wiring electrodes 25A, 25B, 25C have parts formed at the respective edges of the cutouts 15A-C, bonding pad portions disposed in the central region along the center line CL of the substrate 10, and routing portions 25AW, 25BW, 25CW that connect them. The wiring electrodes 23A-C and the wiring electrodes 25A-C are each separated from one another on the upper surface of the substrate 10.

In addition, the wiring electrodes 23A to 23C and the wiring electrodes 25A to 25C are close to one another in respective regions along the center line CL between the cutouts 13A to 13C and the center line CL of the substrate 10 and between the cutouts 15A to 15C and the center line CL of the substrate 10 and extend from the regions along the center line CL to respective both end portions of the upper surface of the substrate 10.

The wiring electrodes 23A to 23C are close to one another in a region along a straight line L1 extending along an arranging direction of the cutouts 13A to 13C. Specifically, extension portions EX that extend along the straight line L1 in respective directions toward the wiring electrodes 23B and 23C are formed at the routing portion 23AW.

Further, the routing portions 23BW and 23CW of the wiring electrodes 23B and 23C are formed to extend along the straight line L1 in directions toward the wiring electrode 23A from respective end portions of the upper surface of the substrate 10. Thus, since the extension portions EX and the routing portions 23AW to 23CW of the wiring electrodes 23A to 23C have the parts extending along the straight line L1, the wiring electrodes 23A to 23C are configured closely in the region along the straight line L1 on the upper surface of the substrate 10.

The wiring electrodes 25A to 25C are close to one another in a region along a straight line L2 extending along an arranging direction of the cutouts 15A to 15C. Specifically, an extension portion EX that extends along the straight line L2 in a direction toward the wiring electrode 25B is formed at the routing portion 25AW. Further, an extension portion EX that extends along the straight line L2 in a direction toward the wiring electrode 25A is formed at the routing portion 25CW.

In addition, the routing portion 25BW of the wiring electrode 25B is formed to extend along the straight line L2 in a direction toward the wiring electrode 25A from each end portion of the upper surface of the substrate 10. Further, the routing portion 25AW of the wiring electrode 25A is formed such that a part opposed to the extension portion EX extends along the straight line L2 toward the extension portion EX of the routing portion 25CW. Thus, since the extension portions EX and the routing portions 25AW to 25CW of the wiring electrodes 25A-C have the parts extending along the straight line L2, the wiring electrodes 25A to 25C are configured closely in the region along the straight line L2 on the upper surface of the substrate 10.

As described above, the wiring electrodes 23A to 23C and 25A to 25C are each configured to be close to one another at the extension portions EX, the routing portions 23AW to 23CW, and the routing portions 25AW to 25CW.

In addition, the respective wiring electrodes 23A-C and the respective wiring electrodes 25A-C reach a back surface of the substrate 10 from the respective edges of the cutouts 13A-C and the cutouts 15A-C on the upper surface of the substrate 10 through respective internal surfaces of the cutouts 13A-C and the cutouts 15A-C.

The wiring electrodes 23A-C and the wiring electrodes 25A-C are formed over the whole circumferences of the respective edges of the cutouts 13A-C and the cutouts 15A-C on the upper surface of the substrate 10. In other words, the respective wiring electrodes 23A-C and the respective wiring electrodes 25A-C are formed to cover regions PA extending over the respective edges of the cutouts 13A-C and the cutouts 15A-C on the upper surface and the lower surface of the substrate 10.

In the embodiment, each of the wiring electrodes 23A-C and wiring electrodes 25A-C is made of copper foil formed on substrate surfaces and copper plating formed on the surfaces of the copper foil on the upper surface and the lower surface of the substrate 10. In addition, the wiring electrodes 23A-C, 25A-C are made of copper plating formed on the internal surfaces of the cutouts so as to cover the internal surfaces. In the embodiment, the thickness of each of the wiring electrodes 23A-C and wiring electrodes 25A-C on the upper surface and the lower surface of the substrate 10 is about 30 μm from the surface of the substrate 10.

The shapes of the wiring electrodes 23A-C and the wiring electrodes 25A-C on the upper surface of the substrate 10 can be designed arbitrarily according to the arrangement of the bonding pad portions and the element placing portions in the central region along the center line CL of the substrate 10. It is only necessary for the wiring electrodes 23A-C and the wiring electrodes 25A-C to be formed over the respective edges of the cutouts 13A-C and the cutouts 15A-C and extend up to respective both end portions of the upper surface of the substrate 10 while being close to one another at the regions along predetermined straight lines in the direction along the center line CL between the cutouts 13A-C and the bonding pad portions with element placing portions and between the cutouts 15 A-C and the bonding pad portions with element placing portions in the central region.

### Light-Emitting Element

The light-emitting elements 41, 43, 45 are light emitting diodes (LEDs) constituted of semiconductors placed on an upper surface of the wiring electrode 23A in the central region of the upper surface of the substrate 10.

In the embodiment, the light-emitting element 41 is an AlGaInP-based LED that emits red light from an upper surface. In the embodiment, the light-emitting elements 43 and 45 are InGaN-based LEDs that emit green and blue light from upper surfaces, respectively. The light-emitting elements 41, 43, 45 are bonded onto the upper surface of the wiring electrode 23A via respective conductive element bonding layers (not illustrated) made from argentum (Ag) paste or the like as a raw material.

The light-emitting element 41 has an anode electrode on a lower surface and a cathode electrode pad on the upper surface. In the light-emitting element 41, the anode electrode on the lower surface is electrically connected to the wiring electrode 23A. Further, in the light-emitting element 41, the cathode electrode pad on the upper surface is electrically connected to the wiring electrode 25A by a bonding wire 41K. Therefore, the light-emitting element 41 has a configuration that is supplied with electric power via the wiring electrode 23A and the wiring electrode 25A.

The light-emitting element 43 has a cathode electrode pad and an anode electrode pad on the upper surface. In the light-emitting element 43, the cathode electrode pad is connected to the wiring electrode 23B by a bonding wire 43A, and the anode electrode pad is connected to the wiring electrode 25B by a bonding wire 43K. Therefore, the light-emitting element 43 has a configuration that is supplied with electric power via the wiring electrode 23B and the wiring electrode 25B.

Similarly to the light-emitting element 43, the light-emitting element 45 has a cathode electrode pad and an anode electrode pad on the upper surface. In the light-emitting element 45, the cathode electrode pad is connected to the wiring electrode 23C by a bonding wire 45A, and the anode electrode pad is connected to the wiring electrode 25C by a bonding wire 45K. Therefore, the light-emitting element 45 has a configuration that is supplied with electric power via the wiring electrode 23C and the wiring electrode 25C. The light-emitting element 43 and the light-emitting element 45 are bonded adjacent to the light-emitting element 41 on the upper surface of the wiring electrode 23A via element bonding layers (not illustrated). A bonding surface between the light-emitting element 43 and the light-emitting element 45 is insulating and is electrically insulated from the wiring electrode 23A.

### Protection Element

The protection element 51 and the protection element 53 are reverse voltage protection elements, such as zener diodes. Each of the protection element 51 and the protection element 53 has a cathode electrode on a lower surface and an anode electrode pad on an upper surface.

In the protection element 51, the cathode electrode on the lower surface is electrically connected to the wiring electrode 23B. Further, in the protection element 51, the anode electrode pad on the upper surface is electrically connected to the wiring electrode 25B by a bonding wire 51A.

In the protection element 53, the cathode electrode on the lower surface is electrically connected to the wiring electrode 23C. Further, in the protection element 53, the anode electrode pad on the upper surface is electrically connected to the wiring electrode 25C by the bonding wire 53A.

Therefore, the protection element 51 and the protection element 53 are connected in parallel with the respective light-emitting elements 43, 45 in reverse polarity between the respective wiring electrodes 23B, 23C and the respective wiring electrodes 25B, 25C.

### First Resin Film, Second Resin Film, and Third Resin Film

The first resin film 31 (indicated by the two-dot chain line in the drawing) is an insulating film made of a resin material having an insulating property, such as epoxy resin. The first resin film 31 is formed to block each of the cutouts 13A-C and cover the wiring electrodes 23A, 23B, 23C at peripheral edges of the cutouts 13A, 13B, 13C on the upper surface of the substrate 10 in the top view.

The first resin film 31 further includes a strip-shaped portion 31B that extends in a strip shape in a region along the straight line L1. The strip-shaped portion 31B covers the upper surfaces of the extension portions EX and the routing portions 23AW-CW of the wiring electrodes 23A-C, which are formed in the region along the straight line L1, and the upper surface of the substrate 10. That is, in the region along the straight line L1, the first resin film 31 covers the upper surface of each of the wiring electrodes 23A-C with the strip-shaped portion 31B and fills the gap between the respective wiring electrodes 23A-C.

The second resin film 32 (indicated by the two-dot chain line in the drawing) is, similarly to the first resin film 31, a film made of a resin material having an insulating property, such as epoxy resin. The second resin film 32 is formed to block each of the cutouts 15A-C and cover the wiring electrodes 25A, 25B, 25C at peripheral edges of the cutouts 15A, 15B, 15C on the upper surface of the substrate 10 in the top view.

The second resin film 32 further includes a strip-shaped portion 32B that extends in a strip shape in a region along the straight line L2. The strip-shaped portion 32B covers the upper surfaces of the extension portions EX and the routing portions 25AW-CW of the wiring electrodes 25A-C, which are formed in the region along the straight line L2, and the upper surface of the substrate 10. That is, in the region along the straight line L2, the second resin film 32 covers the upper surface of each of the wiring electrodes 25A-C with the strip-shaped portion 32B and fills the gap between the respective wiring electrodes 25A-C.

In addition, on the upper surface of the substrate 10, the first resin film 31 and the second resin film 32 covers the regions on the upper surfaces of the wiring electrodes 23A-C and the wiring electrodes 25A-C, respectively, corresponding to the regions PA of the substrate 10 covered by the wiring electrodes 23A-C and by the respective wiring electrodes 25A-C.

As illustrated in FIG. 2, the first resin film 31 and the second resin film 32 enter the cutouts 13A-C and the cutouts 15A-C so as to fit into an inside of each of the cutouts 13A-C and the cutouts 15A-C from above, respectively. That is, the first resin film 31 and the second resin film 32 cover upper end parts of the wiring electrodes 23A, 23B, 23C and the wiring electrodes 25A, 25B, 25C in the cutouts 13A, 13B, 13C and the cutouts 15A, 15B, 15C, respectively.

As illustrated in FIG. 1, in the light-emitting device 100, the first resin film 31 and the second resin film 32 are formed to partially expose respective outer peripheral ends of the wiring electrodes 23A-C and the wiring electrodes 25A-C in the vicinities of the peripheral edges of the regions PA of the cutouts 13A-C and the cutouts 15A-C, respectively. This is because even when non-transparent solder resist ink is used for the first resin film 31 and the second resin film 32, the positions of the wiring electrodes 23A-C and the wiring electrodes 25A-C and orientation of the light-emitting device 100 are viewable in the light-emitting device 100 after manufacturing.

As illustrated in FIG. 2, a third resin film 33 is formed on the lower surface of the substrate 10. The third resin film 33 is formed of the same material as that of the first resin film 31 and the second resin film 32. In addition, the third resin film 33 is formed in a pattern that exposes bonding regions of the wiring electrodes 23A-C and the wiring electrodes 25A-C with bonding members for a mounting substrate on the lower surface of the substrate 10.

In the embodiment, photosensitive solder resist ink (green resist) was used as the first resin film 31, the second resin film 32, and the third resin film 33. The first resin film 31 and the second resin film 32 can avoid unintentional light by the light-emitting elements 41, 43, 45 by using a light-shielding member. This allows the light-emitting device 100 to obtain more desired light distribution. Note that the first resin film 31 and the second resin film 32 may be made of, for example, a member having light absorbency or light reflectivity, such as silicon. In the embodiment, each of the first resin film 31, the second resin film 32, and the third resin film 33 is formed such that the thickness from the upper surface of the substrate 10 is about 20 μm.

Nickel (Ni) and gold (Au) are stacked in sequence on the surface of each of the wiring electrodes 23A-C and wiring electrodes 25A-C exposed from the first resin film 31, the second resin film 32, and the third resin film 33.

### Sealing Member

The sealing member 60 is constituted of a translucent resin material, such as silicone resin, epoxy resin, and acrylic resin, and is formed in the region along the center line CL on the upper surface of the substrate 10.

In the embodiment, the sealing member 60 is formed in the region between the vicinity of the straight line L1 and the vicinity of the straight line L2 on the upper surface of substrate 10, covers the upper surface of the substrate 10 and the respective upper surfaces of the wiring electrodes 23A-C, 25A-C, and seals the light-emitting elements 41, 43, 45 and the protection elements 51, 53. That is, lower end portions of side surfaces in a direction along the center line CL of the sealing member 60 are on the respective upper surfaces of the strip-shaped portions 31B and 32B of the first resin film 31 and the second resin film 32 on the vicinities of the straight line L1 and the straight line L2 on the upper surface of the substrate 10.

As described above, by setting the positions of the lower end portions of the side surfaces of the sealing member 60 to the respective upper surfaces of the strip-shaped portions 31B and 32B of the first and second resin films 31 and 32 and the vicinities on the straight line L1 and the straight line L2, leakage of the sealing member 60 in directions of the respective cutouts can be suppressed in a manufacturing method described below.

### Manufacturing Method of Light-Emitting Device

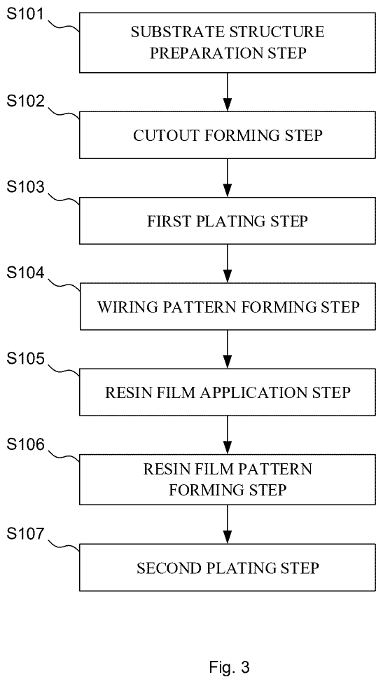

Next, using FIG. 3 to FIG. 9, the manufacturing method of the light-emitting device 100 of the embodiment is described.

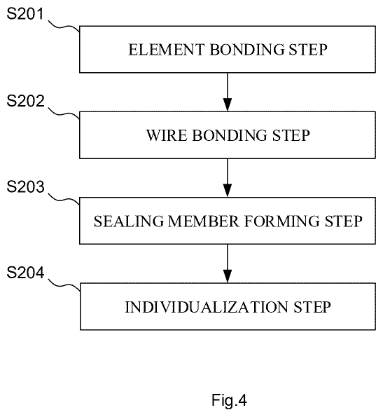

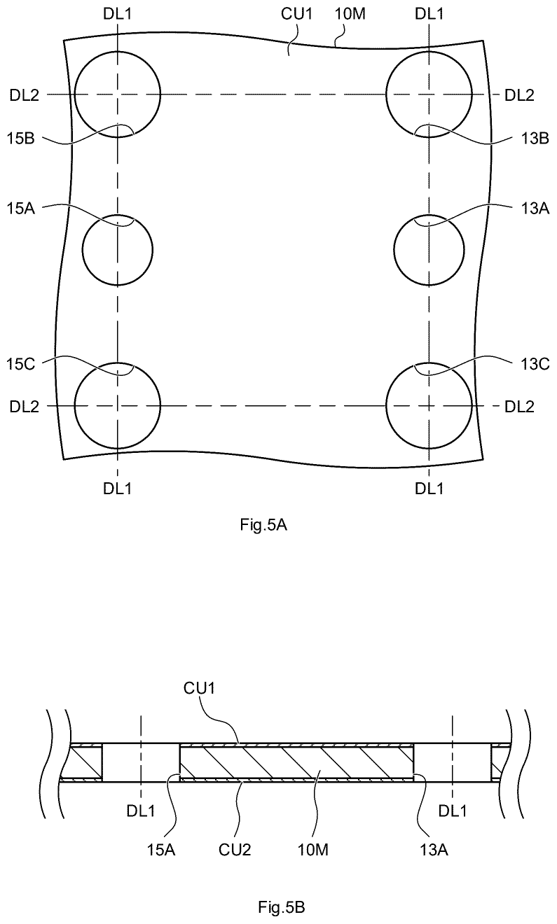

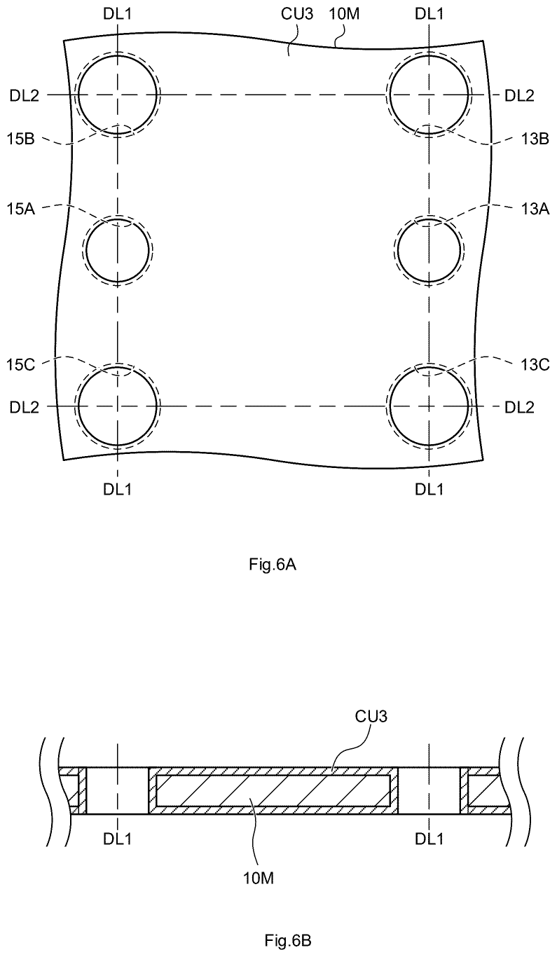

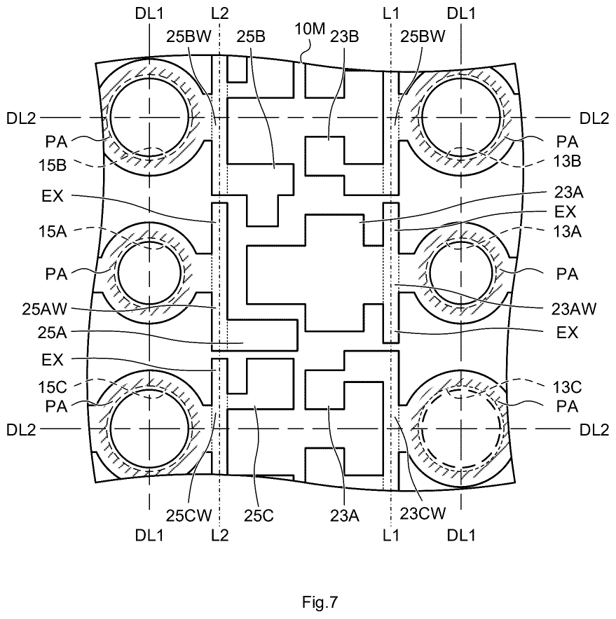

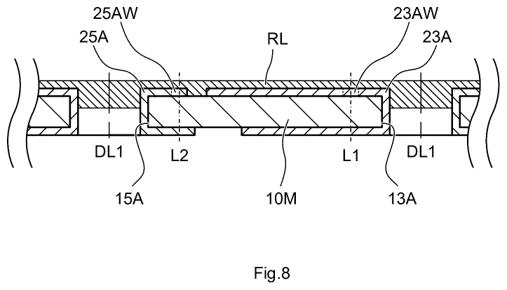

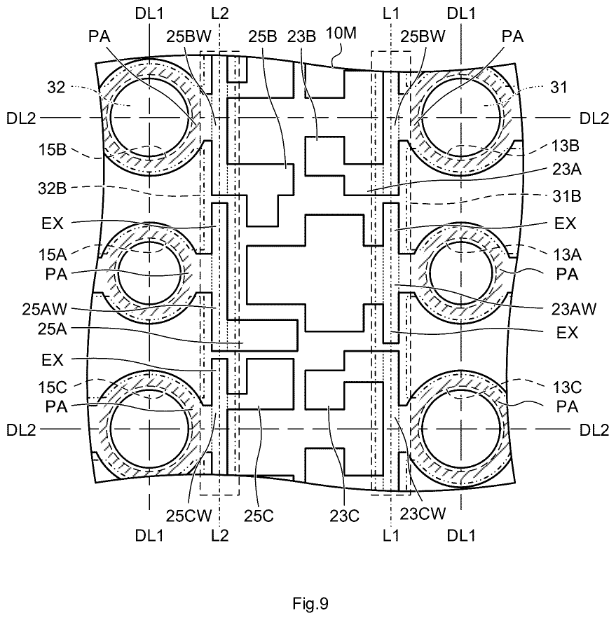

FIG. 3 and FIG. 4 are diagrams illustrating the manufacturing process of the light-emitting device 100 according to the embodiment of the present invention. In addition, FIG. 5 to FIG. 9 illustrate cross-sectional views of the light-emitting device 100 at each step of the manufacturing procedure illustrated in FIG. 3 and FIG. 4. FIG. 5A, FIG. 6A, FIG. 7, and FIG. 9 illustrate a top view of one light-emitting device formation region and its periphery. FIG. 5B, FIG. 6B, and FIG. 8 illustrate a cross-sectional surface corresponding to the line 2-2 illustrated in FIG. 1 at the one light-emitting device formation region and its periphery.

In the description of the manufacturing method below, the cutouts 13A-C, 15A-C of the substrate 10 before the completion of Step S204 (individualization step) are referred to as through holes 13A-C, 15A-C, respectively.

### Step S101

First, a step of preparing a substrate structure 10M (see FIGS. 5A and 5B) used for manufacturing is performed (Step S101, substrate structure preparation step). The substrate structure 10M is a substrate formed by press-bonding a copper foil CU1 onto the upper surface of the substrate 10, which is a flat plate made of glass epoxy having a rectangular upper surface shape, and a copper foil CU2 onto the lower surface. Dicing lines DL1, DL2 are dicing lines used to individualize the light-emitting device 100. That is, the light-emitting device 100 is formed by individualizing by dicing a structure including the substrate structure 10M along the dicing lines DL1, DL2. The copper foils CU1, CU2, for example, are press-bonded onto a glass epoxy substrate and have a thickness of about 18 μm.

### Step S102

Next, as illustrated in FIGS. 5A and 5B, in each light-emitting device formation region, through holes, which become the cutouts 13A-C and the cutouts 15A-C, are formed along the dicing lines DL1 (Step S102, cutout forming step). In this step, the through holes are formed along each of the dicing lines DL1. The through holes 13B, 13C, 15B, and 15C are formed at positions where the dicing lines DL1 intersect with the dicing lines DL2, and the through holes 13A and 15A are formed at the middle points of the adjacent dicing lines DL2. Each of the through holes 13A-C and 15A-C was formed by penetrating the copper foil CU1, the substrate structure 10M, and the copper foil CU2 from above by means of a drill or the like.

### Step S103

Next, as illustrated in FIGS. 6A and 6B, copper plating is applied to inner surfaces of the through holes of the substrate structure 10M and surfaces of the copper foil CU1 and the copper foil CU2 to form a copper layer CU3 that integrally covers the surface of the substrate structure 10M (Step S103, first plating step). In this step, first, copper electroless plating was applied to the substrate structure 10M to form electroless plating layers on the surfaces of the copper foil CU1 and the copper foil CU2 and the inner surfaces of the through holes of the substrate structure 10M. Next, copper electrolytic plating was applied to this substrate structure 10M to form an electrolytic plating layer on the surface of the electroless plating layers, and the copper layer CU3 was formed. The copper layer CU3 includes the copper foil CU1 and the copper foil CU2 as foundation layers on the upper surface and the lower surface of the substrate 10.

### Step S104

Next, as illustrated in FIG. 7, the copper layer CU3 is etched to form the wiring electrodes 23A-C and the wiring electrodes 25A-C in each light-emitting device formation region (Step S104, wiring pattern forming step). In this step, first, a resist mask was formed on the surface of the copper layer CU3 of the substrate structure 10M so as to be the wiring pattern described above. Then, the copper layer CU3 exposed from the resist mask was etched until the surface of the substrate structure 10M was exposed, and each of the wiring electrodes 23A-C, 25A-C was formed. Afterwards, the resist mask on the surface of each wiring electrode was removed.

At this time, the wiring electrodes 23A-C and the wiring electrodes 25A-C opposed between adjacent light-emitting device formation regions were formed to be continuous.

### Step S105

Next, as illustrated in FIG. 8, photosensitive resin RL is applied to the entire upper surface of the substrate structure 10M (Step S105, resin film application step). In this step, the resin RL was applied to the upper surface of the substrate structure 10M collectively by squeegeeing from above the substrate structure 10M using a screen printing machine. At this time, the viscosity, application amount, or squeegeeing condition of the resin RL are set such that the resin RL is applied to (the resin RL enters) the respective upper end parts of the wiring electrodes 23A, 23B, 23C and the wiring electrodes 25A, 25B, 25C in the respective cutouts 13A, 13B, 13C and the respective cutouts 15A, 15B, 15C.

### Step S106

Next, as illustrated in FIG. 9, the resin RL applied to the substrate structure 10M is exposed to light to form the first resin film 31 and the second resin film 32 (Step S106, resin film pattern forming step). In this step, ultraviolet rays were irradiated from above the substrate structure 10M through a photomask using an exposure device to expose the resin RL to ultraviolet rays in the shapes of the first resin film 31 and the second resin film 32 in each light-emitting device formation region.

At this time, the photomask has a pattern in which the resin RL is irradiated with ultraviolet rays in regions of the resin RL that cover the regions of the cutouts 13A-C and the cutouts 15A-C and the regions PA of the substrate 10.

Furthermore, the photomask has a pattern in which the resin RL is irradiated with ultraviolet rays such that, for each row of a plurality of light-emitting device formation regions arranged in the direction along the dicing lines DL1 on which the respective cutouts are formed, the strip-shaped portions 31B and 32B of the first resin film 31 and the second resin film 32 are continuous in regions along the straight lines L1 and L2 up to light-emitting device formation regions at both end portions of the row.

Afterwards, the resin RL in an unexposed portion was removed to form the first resin film 31 and the second resin film 32.

In the embodiment, the case where it is controlled to apply the resin RL to the respective upper end parts of the wiring electrodes 23A-C, 25A-C in the cutouts 13A-C, 15A-C in Step S105 (resin film application step) has been described.

In Step S106 (resin film pattern forming step), the depth of focus of the exposure device may be adjusted to expose the resin RL to light to a desired depth range.

In addition, the third resin film 33 was formed on the lower surface of the substrate structure 10M following Step S106 (resin film pattern forming step). For the formation of the third resin film 33, the resin RL was applied using a metal mask or the like that was opened in the shape of the third resin film 33 during squeegeeing.

### Step S107

Next, plated layers, in which Ni and Au are stacked in sequence on the surfaces of the wiring electrodes 23A-C and the wiring electrodes 25A-C exposed from the respective resin films of the substrate structure 10M, are formed (Step S107, second plating process). In this step, after Ni layers were formed on the surfaces of the wiring electrodes 23A-C and the wiring electrodes 25A-C by electrolytic plating, Au layers were formed on the surfaces of the Ni layers.

### Step S201

Next, as illustrated in FIG. 1, on the upper surface of each light-emitting device formation region, the light-emitting elements 41, 43, 45 and the protection elements 51, 53 are bonded to predetermined positions (Step S201, element bonding step). In this step, first, the substrate structure 10M was set on a die bonding apparatus, and raw material paste of a conductive element bonding layer was applied to each element placing portion on the upper surface of each of the wiring electrodes 23A-C. Next, each element was placed on the raw material paste applied to each element placing portion with each electrode pad facing upward. Afterwards, the substrate structure 10M was heated to harden the raw material paste, and each element was bonded to each wiring electrode 23A-C.

### Step S202

Next, as illustrated in FIG. 1, in each light-emitting device formation region, bonding wires that connect the electrode pad of each element to each wiring electrode are formed (Step S202, wire bonding step). In this step, the substrate structure 10M was set on a bonding device to form each of the bonding wires.

In the light-emitting element 41, first, a metal bump was formed on the electrode pad of the light-emitting element 41 using a metal wire of Au or the like, and then the metal wire was bonded to a bonding pad portion and a metal bump of the wiring electrode 25A to form the bonding wire 41K. Subsequently, the bonding wires 43A, 43K, 45A, 45K, 51A, and 53A were formed using the same method.

### Step S203

Next, as illustrated in FIG. 2, the sealing member 60, which seals each of the light-emitting elements and protection elements, is formed (Step S203, sealing member forming step). In this step, the substrate structure 10M was set in a mold of a molding device, and raw material resin of the sealing member 60 was injected and hardened to form the sealing member 60.

In the embodiment, for each row of a plurality of light-emitting device formation regions arranged in the direction along the dicing lines DL1 on which the respective cutouts were formed, a mold with a recessed portion was used. The recessed portion was formed in the shape of the sealing member 60 continuously up to light-emitting device formation regions at both end portions of the row. That is, the end portions of the recessed portion of the mold on the upper surface side of the substrate structure 10M are positioned in the vicinities of the straight lines L1 and L2 extending over the plurality of light-emitting device formation regions arranged in the above-described row direction.

Accordingly, when the substrate structure 10M is pressed by the mold, the elasticity of the first and second resin films 31, 32 allows the mold and the first and second resin films 31, 32 to be closely contacted even in gap portions between the respective wiring electrodes in the vicinities of the straight lines L1 and L2. Therefore, when the raw material resin of the sealing member 60 is injected, leakage of the raw material resin of the sealing member 60 from the gap portions can be suppressed.

### Step S204

Next, as illustrated in FIG. 1, dicing is performed along the dicing lines DL1 and DL2 to individualize a plurality of light-emitting devices 100 (Step S204, individualization step). In this step, the substrate structure 10M, which was affixed to a dicing sheet, was set to a dicing machine, and a dicing blade was moved in directions of predetermined traveling directions along the dicing lines DL1 and DL2 while being rotated to cut off the substrate structure 10M. That is, dicing was performed to separate the cutouts 13A-C and the cutouts 15A-C formed on the dicing lines DL1 of each substrate structure 10M.

In the manufacturing method of the light-emitting device 100 as described above, the first resin film 31 and the second resin film 32 are formed to cover the upper surfaces of the wiring electrodes 23A-C, 25A-C on the dicing lines DL1 and DL2 and fit into the inside of each of the cutouts 13A-C and the inside of each of the cutouts 15A-C from above.

In other words, the first resin film 31 and the second resin film 32 are formed to cover the regions corresponding to the regions PA of the substrate 10 on the upper surfaces of the wiring electrodes 23A-C, 25A-C, especially the edges of the regions PA along the side surfaces 10S1 and 10S2, respectively, after the individualization of the light-emitting device 100. That is, the first resin film 31 and the second resin film 32 are holding members of the wiring electrodes 23A-C, 25A-C.

This can suppress delamination of each wiring electrode from the substrate 10 by the dicing blade during dicing when the light-emitting devices 100 are individualized. As described above, the first resin film 31 and the second resin film 32 are formed such that they fit into the cutouts in the finished light-emitting device 100 and into the through holes during manufacturing. Accordingly, delamination of the first resin film 31 and the second resin film 32 themselves can be avoided during the individualization, and the loss of delamination prevention effect of the wiring electrodes due to the delamination of the resin films can be avoided. This can suppress a failure in manufacturing the light-emitting device 100.

### Mounted State of Light-Emitting Device

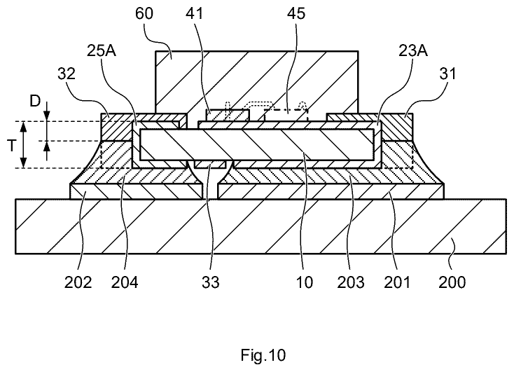

FIG. 10 is a cross-sectional view of the light-emitting device 100 according to the embodiment in a mounted state. Note that FIG. 10 is a cross-sectional view taken along the line 2-2 of the light-emitting device 100 illustrated in FIG. 1.

A mounting substrate 200 is a substrate on which the light-emitting device 100 is mounted. The mounting substrate 200 has a mounting electrode 201 and a mounting electrode 202 on the cross-sectional surface along the line 2-2. Bonding members 203, 204 are bonding members made from paste containing solder and the like as a raw material.

The bonding members 203, 204 are heated and melted to bond the mounting substrate 200 and the light-emitting device 100 on upper surfaces of the mounting electrode 201 and the mounting electrode 202 of the mounting substrate 200.

At the time of melting, the bonding members 203, 204 spread to and wet the respective surfaces of the wiring electrode 23A and the wiring electrode 25A of the light-emitting device 100. That is, the respective bonding members 203 and 204 crawl up along the inner surfaces of the wiring electrode 23A and the wiring electrode 25A formed on the inner surfaces of the cutout 13A and the cutout 15A.

In the light-emitting device 100, the first resin film 31 and the second resin film 32 made of solder resist, which is a material with low affinity with a metal constituting the melted bonding members 203, 204, block the cutouts 13A-C and the cutouts 15A-C of the substrate 10, respectively. Accordingly, with the light-emitting device 100 and the manufacturing method thereof, when the light-emitting device 100 is mounted on a mounting substrate 200, the melted bonding members 203 and 204 crawling up to the upper surface through the internal surfaces of the cutouts can be avoided, and a resulting failure, such as a short circuit of wiring, can be avoided.

In addition, by avoiding the bonding members 203 and 204 excessively crawling up by the first resin film 31 and the second resin film 32, thick fillets of the bonding members 203 and 204 can be formed.

The first and second resin films 31, 32 preferably enter the insides of the cutouts up to a distance D, which is ⅓ or more and ½ or less of a thickness T from upper ends to lower ends of the wiring electrodes 23A-C, 25A-C (T/3≤D≤T/2).

This is because if the distance D is too large, that is, if the resin films excessively enter the insides of the cutouts, the area of each wiring electrode exposed to the inner surface of each of the cutouts 13A-C and cutouts 15A-C decreases, which may cause the bonding strength with a bonding member (solder) to decrease when the light-emitting device 100 is mounted.

Conversely, if the distance D is too small, that is, if entry of the resin films into the cutouts is too small, the first and second resin films 31, 32 are more likely to delaminate, which may cause the above-described delamination prevention effect of wiring and crawling up prevention effect of the bonding member to be lost.

As described above, with the light-emitting device 100 of the embodiment, the mounted light-emitting device 100 can secure high die shear strength and improve mountability.

### Modification

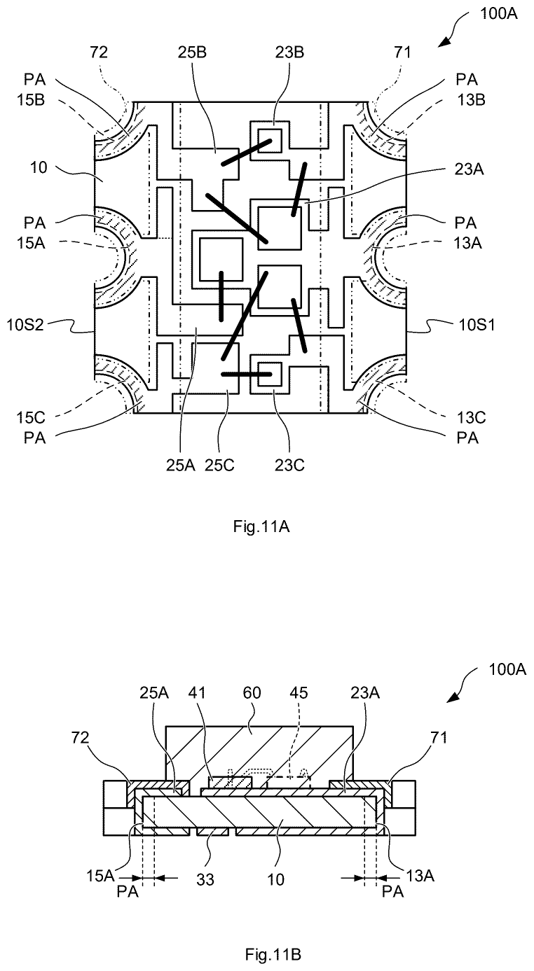

Next, a light-emitting device 100A of a modification is described. FIG. 11A is a top view of the light-emitting device 100A according to the modification. FIG. 11B illustrates a cross-sectional surface of the light-emitting device 100A corresponding to the line 2-2 illustrated in FIG. 1.

The light-emitting device 100A of the modification basically has a similar configuration to the light-emitting device 100 of the embodiment.

The light-emitting device 100A of the modification differs from the embodiment in that a first resin film 71 and a second resin film 72 do not block the respective cutouts 13A-C, 15A-C in a top view.

For example, the light-emitting device 100A of the modification can be achieved by forming through holes that penetrate through respective predetermined regions of the through holes 13A-C and 15A-C of the substrate structure 10M from above by means of a drill or the like after Step S203 (sealing member forming step) illustrated in FIG. 4.

Since the light-emitting device 100A of the modification has a structure in which the first and second resin films 71, 72 are not provided at four corners of an individual light-emitting device formation region of the substrate structure 10M in the top view, chipping of the first and second resin films 71, 72 can be suppressed in Step S204 (individualization step).

Even when the first resin film 71 and the second resin film 72 are formed as described above, the effects similar to those of the embodiment can be provided.

Therefore, with a light-emitting device 100B of the modification, it is possible to improve mountability when the light-emitting device 100B is mounted while suppressing failures in manufacturing the light-emitting device 100B.

Note that in the embodiment and the modification, the cutouts 13A-C and the cutouts 15A-C each have semicircular and fan shapes, but the shapes of the respective cutouts are not limited thereto. The cutouts 13A-C and the cutouts 15A-C may each be formed in semi-oval and quarter-oval shapes or in semi-elliptical and quarter-elliptical shapes.

In the embodiment and the modification, while the first resin film 31 and the second resin film 32 are solder resist ink, for example, transparent or translucent resin films may be used. In this case, the first resin film 31 and the second resin film 32 may be formed in the entire region on the upper surface of the substrate 10, excluding the element placing portions and the bonding portions of each of the wiring electrodes 23A-C and wiring electrodes 25A-C.

Thus, the embodiments described are not intended to limit the scope of the invention. The embodiments described can be performed in various other configurations, and various kinds of omission, replacement, and changes can be made without departing from the gist of the invention. Then, the modifications thereof are also included in the scope and gist of the invention, and are included in the scope of the invention and the equivalents described in the claims.

### DESCRIPTION OF REFERENCE SIGNS

100 Light-emitting device
10 Substrate
13, 15 Cutout
23, 25 Wiring electrode
31, 71, 81 First resin film
32, 72, 82 Second resin film
41, 43, 45 Light-emitting element
51, 53 Protection element
60 Sealing member
200 Mounting substrate
201, 202 Mounting electrode
203, 204 Bonding member

1. A light-emitting device comprising:
an insulating substrate having an approximately rectangular upper surface shape and having a plurality of first cutouts and a plurality of second cutouts, the plurality of first cutouts being formed on one side surface of one set of opposed side surfaces of the substrate, and the plurality of second cutouts being formed on another side surface of the one set of side surfaces of the substrate;
a plurality of first wiring electrodes corresponding respectively to the plurality of first cutouts and each covering a region that extends over an edge of a corresponding one of the plurality of first cutouts on an upper surface of the substrate and a region that extends over an edge of the corresponding one of the plurality of first cutouts on a lower surface of the substrate from an internal surface of the corresponding one of the plurality of first cutouts;
a plurality of second wiring electrodes separated from each of the first wiring electrodes and corresponding respectively to the plurality of second cutouts, each of the second wiring electrodes covering a region that extends over an edge of a corresponding one of the plurality of second cutouts on the upper surface of the substrate and a region that extends over an edge of the corresponding one of the plurality of second cutouts on the lower surface of the substrate from an internal surface of the corresponding one of the plurality of second cutouts;
a first resin film covering a surface of each of the first wiring electrodes in each of regions that extend over edges along the plurality of first cutouts in a top view viewed from a direction perpendicular to the upper surface of the substrate;
a second resin film covering a surface of each of the second wiring electrodes in a region extending over edges along the plurality of second cutouts in the top view; and
a light-emitting element placed on the substrate to allow power to be supplied by the first wiring electrode and the second wiring electrode.

2. The light-emitting device according to claim 1, wherein:
the first resin film extends up to a surface of a part of each of the first wiring electrodes formed on the internal surface of each of the plurality of first cutouts, and
the second resin film extends up to a surface of a part of each of the second wiring electrodes formed on the internal surface of each of the plurality of second cutouts.

3. The light-emitting device according to claim 1, wherein the first resin film and the second resin film are formed to block the plurality of first cutouts and the plurality of second cutouts, respectively, in the top view.

4. The light-emitting device according to claim 2, wherein:
the first resin film coats from an upper end of a part of each of the first wiring electrodes formed on the internal surface of each of the plurality of first cutouts up to a region at a distance of ⅓ or more and ½ or less of a thickness from an upper end to a lower end of the first wiring electrode, and
the second resin film coats from an upper end of a part of each of the second wiring electrodes formed on the internal surface of each of the plurality of second cutouts up to a region at a distance of ⅓ or more and ½ or less of a thickness from an upper end to a lower end of the second wiring electrode.

5. The light-emitting device according to claim 1, wherein:
each of the first wiring electrodes and the second wiring electrodes is made of copper, and
the first resin film and the second resin film are formed to be in contact with the copper of the first wiring electrodes and the second wiring electrodes.

6. The light-emitting device according to claim 5, wherein nickel and gold are stacked in sequence on respective surfaces of the first wiring electrodes and the second wiring electrodes exposed from the first resin film and the second resin film.

7. The light-emitting device according to claim 1, wherein
the plurality of first cutouts with the first wiring electrodes and the plurality of second cutouts with the second wiring electrodes are formed to be paired up with one another on the one set of side surfaces of the substrate, and
a plurality of the light-emitting elements are placed on the substrate according to a number of the pairs.

8. The light-emitting device according to claim 1, further comprising:
a sealing member formed to seal the light-emitting element on the upper surface of the substrate, the sealing member being formed to expose each of regions on respective surfaces of the first wiring electrodes extending over edges along the plurality of first cutouts and on respective surfaces of the second wiring electrodes extending over edges along the plurality of second cutouts.

9. The light-emitting device according to claim 8, wherein:
the first resin film has a strip-shaped portion extending in a strip shape across both end portions of the substrate in a direction along the one set of side surfaces of the substrate between the plurality of first cutouts and the light-emitting element,
the second resin film has a strip-shaped portion extending in a strip shape across both end portions of the substrate in a direction along the one set of side surfaces of the substrate between the plurality of second cutouts and the light-emitting element,
each of the first wiring electrodes has a part extending along the strip-shaped portion of the first resin film at a lower portion of the first resin film,
each of the second wiring electrodes has a part extending along the strip-shaped portion of the second resin film at a lower portion of the second resin film, and
the sealing member is formed such that one of opposed side end portions thereof is placed on the strip-shaped portion of the first resin film and another of the opposed side end portions is placed on the strip-shaped portion of the second resin film.

10. A manufacturing method of the light-emitting device according to claim 1, comprising:
preparing a substrate structure having an insulating substrate and copper foil layers formed on an upper surface and a lower surface of the substrate;
forming a plurality of through holes arranged in a plurality of rows on the upper surface of the substrate structure, each of the plurality of through holes penetrating from the upper surface to the lower surface of the substrate structure;
forming a copper layer on surfaces of the copper foil layers and inner surfaces of the plurality of through holes by plating;
forming a wiring pattern by etching each of the copper foil layers and the copper layer on the upper surface and the lower surface of the substrate;
forming a resin film covering a region along an outer edge of each of the plurality of through holes on a surface of a part of the wiring pattern formed on the upper surface of the substrate structure; and
cutting the substrate structure so as to separate each of the plurality of through holes along dicing lines extending along the plurality of rows.

11. The manufacturing method of a light-emitting device according to claim 10, wherein forming the resin layer comprises:
applying photosensitive resin to the upper surface of the substrate and regions along upper ends of internal surfaces in the wiring pattern formed on inner surfaces of the plurality of through holes by squeegeeing; and
exposing the resin to light to form a resin film covering up to regions along outer edges of the plurality of through holes on a surface of the part of the wiring pattern formed on the upper surface of the substrate structure and surfaces of parts of the wiring pattern formed on the inner surfaces of the plurality of through holes.
